(19) United States
(12) Patent Application Publication
(10) Pub. No.: US 2016/0379995 A1
(43) Pub. Date: Dec. 29, 2016

(54) THIN-FILM TRANSISTOR ARRAY SUBSTRATE AND MANUFACTURING METHOD THEREOF

(71) Applicant: Shenzhen China Star Optoelectronics Technology Co., Ltd., Shenzhen, Guangdong (CN)

(72) Inventor: Zhuming DENG, Shenzhen (CN)

(21) Appl. No.: 14/767,294

(22) PCT Filed: Jul. 7, 2015
(86) PCT No.: PCT/CN2015/083453

§ 371 Date: Aug. 12, 2015

(30) Foreign Application Priority Data
Jun. 29, 2015 (CN) 201510367107.4

(51) Int. Cl. H01L 27/12; H01L 29/786; H01L 29/66

(52) U.S. Cl. CPC H01L 27/124; H01L 27/1222; H01L 27/127; H01L 29/66765; H01L 29/78669; H01L 29/78678

(57) ABSTRACT

A thin-film transistor (TFT) array substrate and a manufacturing method thereof are provided. The TFT array substrate comprises an element lamination substrate, a passivation layer, and pixel electrode layer. The passivation layer is disposed on the element lamination substrate, and is provided with at least one via hole and a groove array, wherein the groove array includes at least two grooves. The pixel electrode layer is disposed on the passivation layer and inside the grooves, wherein the pixel electrode layer is connected to a second signal line layer through the via hole. This can reduce the cost of manufacturing the TFT array substrate, and increase the manufacturing efficiency of the TFT array substrate.

### FIELD OF THE INVENTION

The present invention relates to a technological field of displays, and more particularly to a thin-film transistor (TFT) array substrate and a manufacturing method thereof.

### BACKGROUND OF THE INVENTION

A traditional manufacturing process of a thin-film transistor (TFT) array substrate is first to dispose a via hole on a passivation layer, and dispose grooves on the passivation layer, then dispose a pixel electrode layer on the surface of the passivation layer and inside the grooves. The pixel electrode layer is connected to a data line layer of the TFT array substrate through the via hole.

In the above-mentioned traditional technical solution, disposing the via hole on the passivation layer and disposing the grooves on the passivation layer are respectively executed. That is, disposing the via hole on the passivation layer and disposing the grooves on the passivation layer are two independent steps.

For executing the two above-mentioned independent steps, two different normal mask manufacturing processes are necessary, so that the cost of the above-mentioned technical solution is higher, and the manufacturing efficiency of the TFT array substrate is lower.

Hence, it is necessary to provide a new technical solution to solve the above-mentioned technical problem.

### SUMMARY OF THE INVENTION

The object of the present invention is to provide a thin-film transistor (TFT) array substrate and a manufacturing method thereof which can reduce the cost of manufacturing the TFT array substrate, and increase the manufacturing efficiency of the TFT array substrate.

For solving the above-mentioned problem, the present invention constructs a technical solution as follows:

A TFT array substrate is provided, which comprises: an element lamination substrate comprising a substrate, a first signal line layer, a semiconductor layer, and a second signal line layer; a passivation layer disposed on the element lamination substrate, wherein the passivation layer is provided with at least one via hole and a groove array, and the groove array includes at least two grooves; and a pixel electrode layer disposed on the passivation layer and inside the grooves, wherein the pixel electrode layer is connected to the second signal line layer through the via hole; wherein the grooves and the via hole are formed in one single mask process; wherein a depth of the grooves is greater than or equal to a depth of the via hole.

In the above-mentioned TFT array substrate, the pixel electrode layer comprises: at least two first portions covering the surface of the passivation layer; and at least two second portions bent and extended from the surface of the passivation layer into the groove, and then bent and extended from the inner of the groove to the surface of the passivation layer; wherein the first portions are connected with the second portions.

In the above-mentioned TFT array substrate, the depth of the grooves is equal to a thickness of the passivation layer.

In the above-mentioned TFT array substrate, the first signal line layer is a scan line layer; the semiconductor layer is an amorphous silicon layer or a polycrystalline silicon layer; and the second signal line layer is a data line layer; and the element lamination substrate further comprises a first insulation layer and a second insulation layer; when the semiconductor layer is the amorphous silicon layer, the scan line layer is disposed under the semiconductor layer; the first insulation layer is disposed between the scan line layer and the amorphous silicon layer; the second insulation layer is disposed above the amorphous silicon layer; the data line layer is disposed above the second insulation layer; and the data line layer is connected to the amorphous silicon layer through the second insulation layer; or when the semiconductor layer is the polycrystalline silicon layer, the scan line layer is disposed above the semiconductor layer; the first insulation layer is disposed between the polycrystalline silicon layer and the scan line layer; the second insulation layer is disposed above the scan line layer; the data line layer is disposed above the second insulation layer; and the data line layer is connected to the polycrystalline silicon layer through the first insulation layer and the second insulation layer.

A TFT array substrate is provided, which comprises: an element lamination substrate comprising a substrate, a first signal line layer, a semiconductor layer, and a second signal line layer; a passivation layer disposed on the element lamination substrate, wherein the passivation layer is provided with at least one via hole and a groove array, and the groove array includes at least two grooves; and a pixel electrode layer disposed on the passivation layer and inside the grooves, wherein the pixel electrode layer is connected to the second signal line layer through the via hole.

In the above-mentioned TFT array substrate, the grooves and the via hole are formed in one single mask process.

In the above-mentioned TFT array substrate, the pixel electrode layer comprises: at least two first portions covering the surface of the passivation layer; and at least two second portions bent and extended from the surface of the passivation layer into the groove, and then bent and extended from the inner of the groove to the surface of the passivation layer; wherein the first portions are connected with the second portions.

In the above-mentioned TFT array substrate, a depth of the grooves is greater than or equal to a depth of the via hole.

In the above-mentioned TFT array substrate, a depth of the grooves is equal to a thickness of the passivation layer.

In the above-mentioned TFT array substrate, the first signal line layer is a scan line layer; the semiconductor layer is an amorphous silicon layer or a polycrystalline silicon layer; and the second signal line layer is a data line layer; and the element lamination substrate further comprises a first insulation layer and a second insulation layer.

In the above-mentioned TFT array substrate, when the semiconductor layer is the amorphous silicon layer, the scan line layer is disposed under the semiconductor layer; the first insulation layer is disposed between the scan line layer and the amorphous silicon layer; the second insulation layer is disposed above the amorphous silicon layer; the data line layer is disposed above the second insulation layer; and the data line layer is connected to the amorphous silicon layer through the second insulation layer.

In the above-mentioned TFT array substrate, when the semiconductor layer is the polycrystalline silicon layer, the scan line layer is disposed above the semiconductor layer; the first insulation layer is disposed between the polycrystalline silicon layer and the scan line layer; the second insulation layer is disposed above the scan line layer; the data line layer is disposed above the second insulation layer; and the data line layer is connected to the polycrystalline silicon layer through the first insulation layer and the second insulation layer.

A manufacturing method of a TFT array substrate, which comprises following steps: A. forming an element lamination substrate, wherein the element lamination substrate comprises a substrate, a first signal line layer, a semiconductor layer, and a second signal line layer; B. disposing a passivation layer on the element lamination substrate; C. executing a mask process to the passivation layer, wherein at least one via hole and a groove array are formed on a surface of the passivation layer, and the groove array includes at least two grooves; and D. disposing a pixel electrode layer on the surface and inside the grooves, wherein the pixel electrode layer is connected to the second signal line layer through the via hole.

In the above-mentioned manufacturing method of the TFT array substrate, the grooves and the via hole are formed in one single mask process.

In the above-mentioned manufacturing method of the TFT array substrate, the pixel electrode layer comprises: at least two first portions covering the surface of the passivation layer; and at least two second portions bent and extended from the surface of the passivation layer into the groove, and then bent and extended from the inner of the groove to the surface of the passivation layer; wherein the first portions are connected with the second portions.

In the above-mentioned manufacturing method of the TFT array substrate, a depth of the grooves is greater than or equal to a depth of the via hole.

In the above-mentioned manufacturing method of the TFT array substrate, the depth of the grooves is equal to a thickness of the passivation layer.

In the above-mentioned manufacturing method of the TFT array substrate, the first signal line layer is a scan line layer; the semiconductor layer is an amorphous silicon layer or a polycrystalline silicon layer; and the second signal line layer is a data line layer; and the element lamination substrate further comprises a first insulation layer and a second insulation layer.

In the above-mentioned manufacturing method of the TFT array substrate, when the semiconductor layer is the amorphous silicon layer, the scan line layer is disposed under the semiconductor layer; the first insulation layer is disposed between the scan line layer and the amorphous silicon layer; the second insulation layer is disposed above the amorphous silicon layer; the data line layer is disposed above the second insulation layer; and the data line layer is connected to the amorphous silicon layer through the second insulation layer.

In the above-mentioned manufacturing method of the TFT array substrate, when the semiconductor layer is the polycrystalline silicon layer, the scan line layer is disposed above the semiconductor layer; the first insulation layer is disposed between the polycrystalline silicon layer and the scan line layer; the second insulation layer is disposed above the scan line layer; the data line layer is disposed above the second insulation layer; and the data line layer is connected to the polycrystalline silicon layer through the first insulation layer and the second insulation layer.

Compared with a traditional technical solution, the above-mentioned technical solution can save one of the mask processes, so that it is advantageous in reducing the cost of manufacturing the TFT array substrate, and in increasing the manufacturing efficiency of the TFT array substrate.

The above-mention contents of the present invention can be best understood by referring to the following detailed description of the preferred embodiments and the accompanying drawings.

### DESCRIPTION OF THE DRAWINGS

FIGS. 1 to 4 are schematic views of a manufacturing method of a thin-film transistor (TFT) array substrate according to the present invention.

FIG. 5 is a flow chart of the manufacturing method of the TFT array substrate according to the present invention.

### DETAILED DESCRIPTION OF THE PREFERRED EMBODIMENTS

The word “exemplary” is used herein to mean serving as an example, instance, or illustration. In addition, the articles “a” and “an” as used in this application and the appended claims may generally be construed to mean “one or more” unless specified otherwise or clear from context to be directed to a singular form.

Refer now to FIG. 4, which is a schematic view of a thin-film transistor (TFT) array substrate manufactured by a manufacturing method of a TFT array substrate according to the present invention.

A TFT array substrate according to the present invention comprises an element lamination substrate 101, a passivation layer 201, and pixel electrode layer 401. The element lamination substrate 101 comprises a substrate 1011, a first signal line layer 1012, a semiconductor layer 1014, and a second signal line layer 1017. Furthermore, the element lamination substrate 101 further comprises a first insulation layer 1013, a second insulation layer 1015, and a drain electrode line layer 1016.

The first signal line layer 1012 can be a scan line layer; the semiconductor layer 1014 can be an amorphous silicon layer or a polycrystalline silicon layer; and the second signal line layer 1017 can be a data line layer. The scan line layer is disposed under the semiconductor layer 1014 (the semiconductor layer 1014 is the amorphous silicon layer); the first insulation layer 1013 is disposed between the scan line layer and the amorphous silicon layer; the second insulation layer 1015 is disposed above the amorphous silicon layer; the data line layer is disposed above the second insulation layer 1015; and the data line layer is connected to the amorphous silicon layer through the second insulation layer 1015. Alternatively, The scan line layer is disposed above the semiconductor layer 1014 (the semiconductor layer 1014 is the polycrystalline silicon layer); the first insulation layer 1013 is disposed between the polycrystalline silicon layer and the scan line layer; the second insulation layer 1015 is disposed above the scan line layer; the data line layer is disposed above the second insulation layer 1015; and the data line layer is connected to the polycrystalline silicon layer through the first insulation layer 1013 and the second insulation layer 1015.

The passivation layer 201 is disposed on the element lamination substrate 101, wherein the passivation layer 201 is provided with at least one via hole 302 and a groove array 301, and the groove array 301 includes at least two grooves 3011.

The pixel electrode layer 401 is disposed on the passivation layer 201 and inside the grooves 3011, wherein the pixel electrode layer 401 is connected to the second signal line layer 1017 through the via hole 302.

In the embodiment, the grooves 3011 and the via hole 302 are formed in one single mask process.

Compared with a traditional technical solution, the above-mentioned technical solution can save one of the mask processes, so that it is advantageous in reducing the cost of manufacturing the TFT array substrate, and in increasing the manufacturing efficiency of the TFT array substrate.

In the embodiment, the pixel electrode layer 401 comprises at least two first portions and at least two second portions.

The first portions cover the surface of the passivation layer 201.

The second portions are bent and extended from the surface of the passivation layer 201 into the groove 3011, and then bent and extended from the inner of the groove 3011 to the surface of the passivation layer 201.

The first portions are connected with the second portions.

That is, the passivation layer 201 is configured to rise and fall, and whole of the pixel electrode layer 401 is attached to the crenellated passivation layer 201. In the other words, whole of the pixel electrode layer 401 attached to the crenellated passivation layer 201, which is advantageous in increasing the display quality of a display panel which corresponds to the TFT array substrate (for example, having a higher penetration rate).

In the embodiment, the depth H1 of the grooves 3011 is greater than or equal to the depth H2 of the via hole 302.

That is advantageous in ensuring that: after executing one of the mask process to the passivation layer 201, the second signal line layer 1017 which is inside the via hole 302 is not coved by the passivation layer 201, so as to guarantee that the pixel electrode layer 401 has a good contact with the second signal line layer 1017.

In the embodiment, the depth H1 of the grooves 3011 is equal to the thickness of the passivation layer 201. That is, the grooves 3011 are passed through the passivation layer 201.

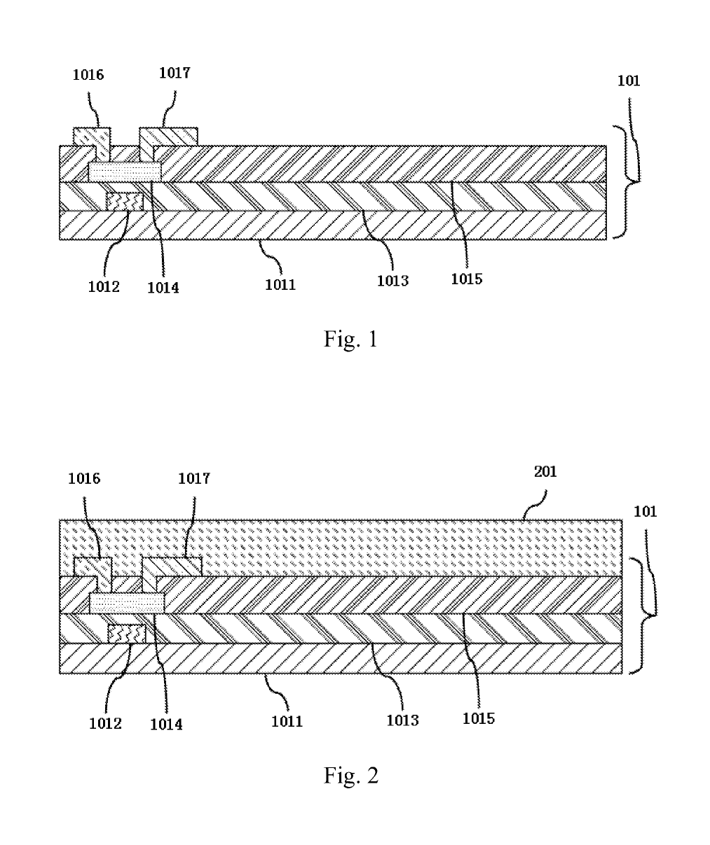

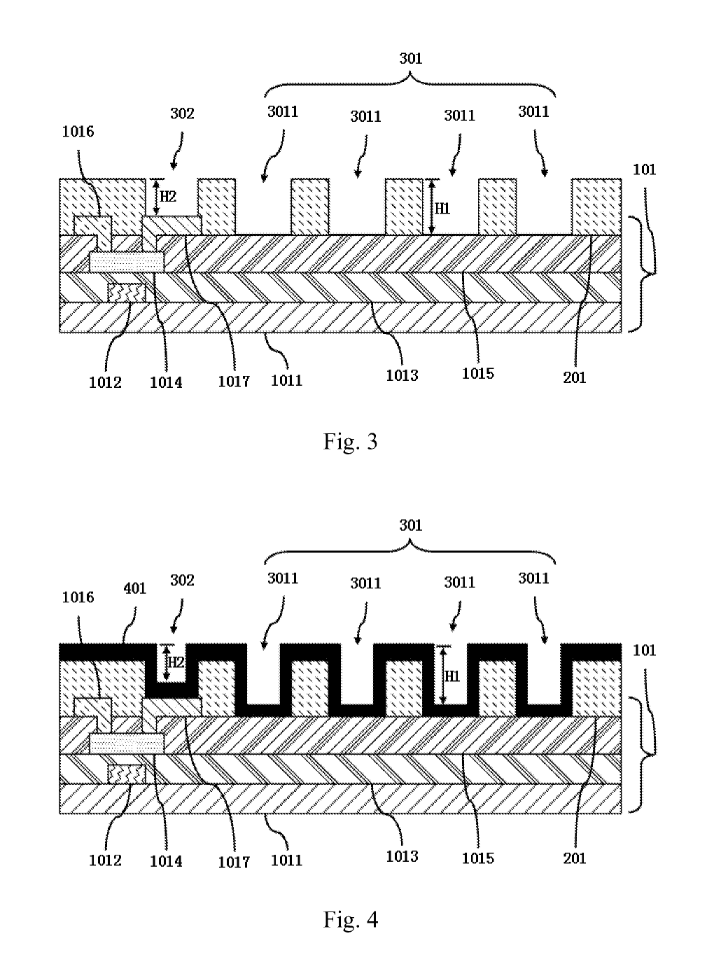

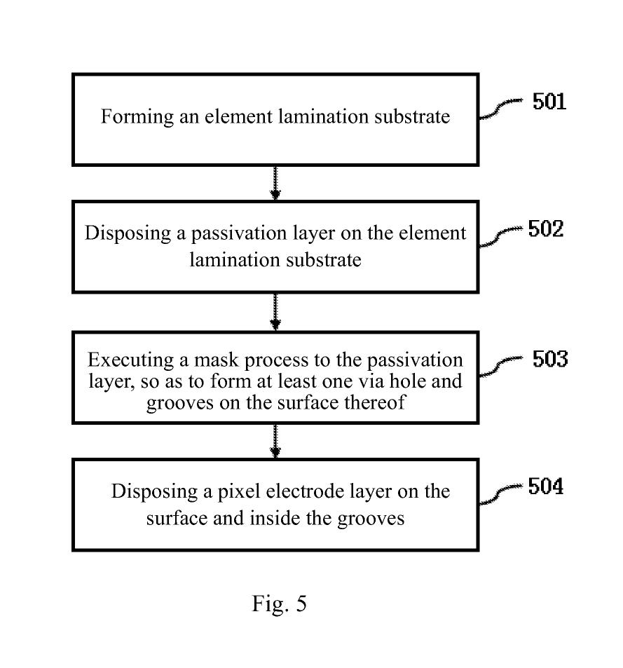

Refer now to FIGS. 1 to 5. FIGS. 1 to 4 are schematic views of a manufacturing method of the TFT array substrate according to the present invention; and FIG. 5 is a flow chart of the manufacturing method of the TFT array substrate according to the present invention.

A manufacturing method of the TFT array substrate according to the present invention comprises following steps:

A. (Step 501) forming an element lamination substrate 101, wherein the element lamination substrate 101 comprises a substrate 1011, a first signal line layer 1012, a semiconductor layer 1014, and a second signal line layer 1017;

B. (Step 502) disposing a passivation layer 201 on the element lamination substrate 101;

C. (Step 503) executing a mask process to the passivation layer 201, wherein a via hole 302 and a groove array 301 are formed on a surface of the passivation layer 201, and the groove array 301 includes at least two grooves 3011; and

D. (Step 504) disposing a pixel electrode layer 401 on the surface and inside the grooves 3011, wherein the pixel electrode layer 401 is connected to the second signal line layer 1017 through the via hole 302.

In the embodiment, the grooves 3011 and the via hole 302 are formed in one single mask process. That is, the step C is:

Executing one of the mask process to the passivation layer 201, so as to simultaneously form the grooves 3011 and the via hole 302.

Compared with a traditional technical solution, the above-mentioned technical solution can save one of the mask processes, so that it is advantageous in reducing the cost of manufacturing the TFT array substrate, and in increasing the manufacturing efficiency of the TFT array substrate.

In the embodiment, the pixel electrode layer 401 comprises at least two first portions and at least two second portions.

The first portions cover the surface of the passivation layer 201.

The second portions are bent and extended from the surface of the passivation layer 201 into the groove 3011, and then bent and extended from the inner of the groove 3011 to the surface of the passivation layer 201.

The first portions are connected with the second portions.

That is, the passivation layer 201 is configured to rise and fall, and whole of the pixel electrode layer 401 is attached to the crenellated passivation layer 201. In the other words, whole of the pixel electrode layer 401 attached to the crenellated passivation layer 201 is advantageous in increasing the display quality for a display panel which corresponds to the TFT array substrate (for example, having a higher penetration rate).

In the embodiment, the depth H1 of the grooves 3011 is greater than or equal to the depth H2 of the via hole 302.

That is advantageous in ensuring that: after executing one of the mask process to the passivation layer 201, the second signal line layer 1017 which inside the via hole 302 is not coved by the passivation layer 201, so as to guarantee that the pixel electrode layer 401 has a good contact with the second signal line layer 1017.

In the embodiment, the depth H1 of the grooves 3011 is equal to the thickness of the passivation layer 201. That is, the grooves 3011 pass through the passivation layer 201.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such a feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

The present invention has been described with preferred embodiments thereof and it is understood that many changes and modifications to the described embodiment can be carried out without departing from the scope and the spirit of the invention that is intended to be limited only by the appended claims.

What is claimed is:

1. A thin-film transistor (TFT) array substrate, comprising:
an element lamination substrate, comprising:
a substrate;
a first signal line layer;
a semiconductor layer; and
a second signal line layer;
a passivation layer disposed on the element lamination substrate, wherein the passivation layer is provided with at least one via hole and a groove array, and the groove array includes at least two grooves; and
a pixel electrode layer disposed on the passivation layer and inside the grooves, wherein the pixel electrode layer is connected to the second signal line layer through the via hole;
wherein the grooves and the via hole are formed in one single mask process;
wherein a depth of the grooves is greater than or equal to a depth of the via hole.

2. The TFT array substrate according to claim 1, wherein the pixel electrode layer comprises:
at least two first portions covering the surface of the passivation layer; and
at least two second portions bent and extended from the surface of the passivation layer into the groove, and then bent and extended from the inner of the groove to the surface of the passivation layer;
wherein the first portions are connected with the second portions.

3. The TFT array substrate according to claim 1, wherein the depth of the grooves is equal to a thickness of the passivation layer.

4. The TFT array substrate according to claim 1, wherein the first signal line layer is a scan line layer; the semiconductor layer is an amorphous silicon layer or a polycrystalline silicon layer; and the second signal line layer is a data line layer; and
the element lamination substrate further comprises a first insulation layer and a second insulation layer;
when the semiconductor layer is the amorphous silicon layer, the scan line layer is disposed under the semiconductor layer; the first insulation layer is disposed between the scan line layer and the amorphous silicon layer; the second insulation layer is disposed above the amorphous silicon layer; the data line layer is disposed above the second insulation layer; and the data line layer is connected to the amorphous silicon layer through the second insulation layer; or
when the semiconductor layer is the polycrystalline silicon layer, the scan line layer is disposed above the semiconductor layer; the first insulation layer is disposed between the polycrystalline silicon layer and the scan line layer; the second insulation layer is disposed above the scan line layer; the data line layer is disposed above the second insulation layer; and the data line layer is connected to the polycrystalline silicon layer through the first insulation layer and the second insulation layer.

5. A thin-film transistor (TFT) array substrate, comprising:
an element lamination substrate, comprising:
a substrate;
a first signal line layer;
a semiconductor layer; and
a second signal line layer;
a passivation layer disposed on the element lamination substrate, wherein the passivation layer is provided with at least one via hole and a groove array, and the groove array includes at least two grooves; and
a pixel electrode layer disposed on the passivation layer and inside the grooves, wherein the pixel electrode layer is connected to the second signal line layer through the via hole.

6. The TFT array substrate according to claim 5, wherein the grooves and the via hole are formed in one single mask process.

7. The TFT array substrate according to claim 5, wherein the pixel electrode layer comprises:
at least two first portions covering the surface of the passivation layer; and
at least two second portions bent and extended from the surface of the passivation layer into the groove, and then bent and extended from the inner of the groove to the surface of the passivation layer;
wherein the first portions are connected with the second portions.

8. The TFT array substrate according to claim 5, wherein a depth of the grooves is greater than or equal to a depth of the via hole.

9. The TFT array substrate according to claim 5, wherein a depth of the grooves is equal to a thickness of the passivation layer.

10. The TFT array substrate according to claim 5, wherein the first signal line layer is a scan line layer; the semiconductor layer is an amorphous silicon layer or a polycrystalline silicon layer; and the second signal line layer is a data line layer; and the element lamination substrate further comprises a first insulation layer and a second insulation layer.

11. The TFT array substrate according to claim 10, wherein when the semiconductor layer is the amorphous silicon layer, the scan line layer is disposed under the semiconductor layer; the first insulation layer is disposed between the scan line layer and the amorphous silicon layer; the second insulation layer is disposed above the amorphous silicon layer; the data line layer is disposed above the second insulation layer; and the data line layer is connected to the amorphous silicon layer through the second insulation layer.

12. The TFT array substrate according to claim 10, wherein when the semiconductor layer is the polycrystalline silicon layer, the scan line layer is disposed above the semiconductor layer; the first insulation layer is disposed between the polycrystalline silicon layer and the scan line layer; the second insulation layer is disposed above the scan line layer; the data line layer is disposed above the second insulation layer; and the data line layer is connected to the polycrystalline silicon layer through the first insulation layer and the second insulation layer.

13. A manufacturing method of a thin-film transistor (TFT) array substrate, comprising following steps:
A. forming an element lamination substrate, wherein the element lamination substrate comprises a substrate, a first signal line layer, a semiconductor layer, and a second signal line layer;
B. disposing a passivation layer on the element lamination substrate;
C. executing a mask process to the passivation layer, wherein at least one via hole and a groove array are formed on a surface of the passivation layer, and the groove array includes at least two grooves; and
D. disposing a pixel electrode layer on the surface and inside the grooves, wherein the pixel electrode layer is connected to the second signal line layer through the via hole.

14. The manufacturing method of the TFT array substrate according to claim 13, wherein the grooves and the via hole are formed in one single mask process.

15. The manufacturing method of the TFT array substrate according to claim 13, wherein the pixel electrode layer comprises:
at least two first portions covering the surface of the passivation layer; and
at least two second portions bent and extended from the surface of the passivation layer into the groove, and then bent and extended from the inner of the groove to the surface of the passivation layer;
wherein the first portions are connected with the second portions.

16. The manufacturing method of the TFT array substrate according to claim 13, wherein a depth of the grooves is greater than or equal to a depth of the via hole.

17. The manufacturing method of the TFT array substrate according to claim 16, wherein the depth of the grooves is equal to a thickness of the passivation layer.

18. The manufacturing method of the TFT array substrate according to claim 13, wherein the first signal line layer is a scan line layer; the semiconductor layer is an amorphous silicon layer or a polycrystalline silicon layer; and the second signal line layer is a data line layer; and the element lamination substrate further comprises a first insulation layer and a second insulation layer.

19. The manufacturing method of the TFT array substrate according to claim 18, wherein when the semiconductor layer is the amorphous silicon layer, the scan line layer is disposed under the semiconductor layer; the first insulation layer is disposed between the scan line layer and the amorphous silicon layer; the second insulation layer is disposed above the amorphous silicon layer; the data line layer is disposed above the second insulation layer; and the data line layer is connected to the amorphous silicon layer through the second insulation layer.

20. The manufacturing method of the TFT array substrate according to claim 18, wherein when the semiconductor layer is the polycrystalline silicon layer, the scan line layer is disposed above the semiconductor layer; the first insulation layer is disposed between the polycrystalline silicon layer and the scan line layer; the second insulation layer is disposed above the scan line layer; the data line layer is disposed above the second insulation layer; and the data line layer is connected to the polycrystalline silicon layer through the first insulation layer and the second insulation layer.
